(19) United States
(12) Patent Application Publication
(10) Pub. No.: US 2007/0087474 A1
(43) Pub. Date: Apr. 19, 2007

(54) Assembly process for out-of-plane MEMS and three-axis sensors

(76) Inventors: E. Jesper Eklund, Costa Mesa, CA (US); Andrei M. Shkel, Irvine, CA (US)

Correspondence Address: Daniel L. Dawes;Myers Dawes Andras & Sherman LLP, Suite 1150, 19900 MacArthur Boulevard, Irvine, CA, 92612, US

(21) Appl. No.: 11/541,072

(22) Filed: Sep. 29, 2006

Related U.S. Application Data
(60) Provisional application No. 60/726,684, filed on Oct. 13, 2005.
(60) Provisional application No. 60/726,723, filed on Oct. 13, 2005.

(51) Int. Cl. H01L 21/00; H01L 23/495

(52) U.S. Cl. 438/106; 438/123; 257/676

(57) ABSTRACT

A method of assembling a three dimensional micromachined structure comprising the steps of defining a cavity in a holder wafer having a thick upper layer, providing a plurality of fingers in the thick upper layer extending from the holder wafer into the cavity, and disposing an out-of-plane wafer into the cavity in the holder wafer in engagement with the fingers to hold the out-of-plane wafer in place in an out-of-plane position with respect to the holder wafer. The invention also includes an apparatus made according to any combination of the above method steps and/or the structure of the apparatus which is fabricated from any combination of those method steps.

### RELATED APPLICATIONS

The present application is related to U.S. Provisional Patent Application, Ser. No. 60/726,684, filed on Oct. 13, 2005, and Ser. No. 60/726,723, filed on Oct. 13, 2005, which are incorporated herein by reference and to which priority is claimed pursuant to 35 USC 119.

### BACKGROUND OF THE INVENTION

1. Field of the Invention

The invention relates to methods for the assembly of three dimensional microelectromechanical systems (MEMS).

2. Description of the Prior Art

Microassembly techniques have been proposed for optical MEMS. In the publications listed below it is disclosed that a deposited layer of, for example, silicon carbide or silicon nitride serves as elastic flexures above a V-groove. Optical MEMS components can be inserted into the V-groove from the top and are held in place by the flexures. However, this method is only used for passive components. Further disclosure can be found in P. Boyle et.al., “Packaging solutions for MEMS/MOEMS using thin films as mechanical components”, Proceedings of SPIE, vol. 4755, pp. 496-507, 2002, and R. Syms et.al., “Optical MEMS for telecoms”, Materials Today, vol. 5, pp. 26-35, 2002

Three-axis sensors are often made by mounting three single-axis sensors perpendicularly on a machined cube-type structure. However, it is very difficult to perfectly align the three different sensors perpendicularly when using this technique. Also, all three sensors should ideally have the same center of gravity, which is very hard to obtain with macro-scale assembly.

### BRIEF SUMMARY OF THE INVENTION

In the method of the illustrated embodiment of the invention, a sensor or accelerometer fabricated into an out-of-plane wafer or chip can be inserted into a cavity in a holder wafer, which in addition to holding the sensor in place also provides electrical conduction between the inserted sensor and the holder wafer or substrate. The use of SOI holder wafers allows for a more robust structure, since fingers for holding and contacting the out-of-plane wafer can be fabricated from the device layer in an SOI wafer, which fingers are much thicker than the very thin layer of silicon nitride or silicon carbide in the prior art assemblies.

The illustrated embodiment of the invention is thus a method for assembly of three-dimensional micromachined devices. By etching a cavity in silicon-on-insulator (SOI) wafer and placing a second chip or wafer vertically in the cavity, a three-dimensional structure is obtained. In addition to allowing for mounting of a device perpendicular to a surface of the SOI wafer, this process also enables post-fabrication assembly of three-axis sensors.

When compared to macro-scale mounting of a sensor perpendicular to a surface (or relative to another sensor), the micro-scale assembly technique of the illustrated embodiment is easier to control. Since the angles and cavities are defined with photolithography, any deviation from perpendicularity is determined mainly by fabrication imperfections. In contrast, the precision of prior art macro-scale assembly relies on machining of the mounting block and the skill of the assembler.

The micro-scale assembly process also allows for mounting of three sensors very close together, which means that the center of gravity of each sensor is very close to the center of gravity of the other sensors, which is a desirable property in three-axis sensors.

Thus, it can be understood that the illustrated embodiment of the invention can be used to mount in-plane sensors, or passive components, perpendicular to a surface. It also enables the assembly of three-axis sensors. For example, three-axis accelerometers can be manufactured with this process, which can be used for acceleration measurements, including, but not limited to, the following applications: inertial navigation systems, impact testing, and structural monitoring.

More particularly, the illustrated embodiment of the invention is characterized as a method of assembling a three dimensional micromachined structure comprising the steps of: defining a cavity in a holder wafer having a thick upper layer; providing a plurality of fingers in the thick upper layer extending from the holder wafer into the cavity; and disposing an out-of-plane wafer into the cavity in the holder wafer in engagement with the fingers to hold the out-of-plane wafer in place in an out-of-plane position with respect to the holder wafer.

In one embodiment the method further comprises the step of providing an electrical connection through the fingers between the out-of-plane wafer and the holder wafer.

In another embodiment the step of disposing the out-of-plane wafer into the cavity in the holder wafer further comprises affixing the out-of-plane wafer in the cavity of the holder wafer to provide a robust structure.

In still another embodiment the method further comprises the step of defining at least one groove in the out-of-plane wafer for engagement with the fingers and where disposing the out-of-plane wafer into the cavity in the holder wafer comprises sliding the fingers into the groove.

The step of defining at least one groove in the out-of-plane wafer for engagement with the fingers comprises defining two grooves in the out-of-plane wafer, and where disposing the out-of-plane wafer into the cavity in the holder wafer comprises sliding the fingers into the two grooves. Preferably, the step of defining two grooves in the out-of-plane wafer comprises defining two opposing grooves in the out-of-plane wafer.

The step of providing the plurality of fingers in the thick upper layer extending from the holder wafer into the cavity comprises providing fingers in the thick upper layer extending from the holder wafer into the cavity. The fingers may be provided on a single side or two opposing sides of the cavity in the thick upper layer.

The illustrated embodiment of the invention is still further characterized as a method of assembling a three dimensional microelectromachined structure (MEMS) including active MEMS components in a three dimensional assembly comprising: etching a cavity in silicon-on-insulator (SOI) holder wafer having a thick device layer; engaging an out-of-plane wafer including active MEMS devices with the holder wafer to vertically extend the out-of-plane wafer from the holder wafer, engagement of the out-of-plane wafer and holder wafer causing the out-of-plane wafer and holder wafer to be orthogonally oriented with respect to each other; and electrically coupling the out-of-plane wafer and holder wafer together to obtain a three-dimensional active MEMS assembly.

The step of electrically coupling the out-of-plane wafer and holder wafer together comprises providing a plurality of fingers extending from the holder wafer onto conductors on the out-of-plane wafer, and engaging the out-of-plane wafer with the holder wafer with the fingers to hold the out-of-plane wafer in place in an out-of-plane position with respect to the holder wafer and to electrically couple conductors on the out-of-plane wafer with conductors on the holder wafer.

The step of engaging the out-of-plane wafer into the cavity to extend vertically from the cavity comprises positioning three accelerometers close together with a negligible distance between the center of gravity of each of the three accelerometers.

The invention also includes within its scope and embodiments an apparatus made according to any combination of the above method steps and/or the structure of the apparatus which is fabricated from any combination of those method steps.

While the apparatus and method has or will be described for the sake of grammatical fluidity with functional explanations, it is to be expressly understood that the claims, unless expressly formulated under 35 USC 112, are not to be construed as necessarily limited in any way by the construction of “means” or “steps” limitations, but are to be accorded the full scope of the meaning and equivalents of the definition provided by the claims under the judicial doctrine of equivalents, and in the case where the claims are expressly formulated under 35 USC 112 are to be accorded full statutory equivalents under 35 USC 112. The invention can be better visualized by turning now to the following drawings wherein like elements are referenced by like numerals.

### BRIEF DESCRIPTION OF THE DRAWINGS

FIG. 1a is a top plan view of an out-of-plane wafer including an active MEMS component in which the wafer is shown in isolation of any combination with any other wafer.

FIG. 1b is a top plan view of a holder wafer shown in isolation of any combination with any other wafer.

FIG. 1c is a top plan view of the holder wafer of FIG. 1b showing partial insertion of the wafer of FIG. 1a into a gap defined in the holder wafer.

FIG. 1d is a top plan view of a holder wafer shown with the wafer of FIG. 1a completely inserted.

FIG. 1e is a side plan view, as seen through the section line 1-1 of FIG. 1d, of an embodiment of an assembled out-of-plane wafer and holder wafer in which locking grooves are defined in the out-of-plane wafer for a plurality of opposing fingers provided on the holder wafer.

FIG. 2 is a perspective view of the assembled out-of-plane wafer and holder wafer of FIGS. 1a-1d.

FIG. 3 is a perspective view of the assembled out-of-plane wafer in which one orthogonally oriented accelerometer has been defined and a holder wafer in which two orthogonally oriented accelerometers have been defined to provide a three dimensional, three-axis accelerometer.

The invention and its various embodiments can now be better understood by turning to the following detailed description of the preferred embodiments which are presented as illustrated examples of the invention defined in the claims. It is expressly understood that the invention as defined by the claims may be broader than the illustrated embodiments described below.

### DETAILED DESCRIPTION OF THE PREFERRED EMBODIMENTS

A method for assembling three-dimensional micromachined sensors or passive or active MEMS devices is disclosed. By etching a cavity 20 in silicon-on-insulator (SOI) wafers 14 and placing a second chip or wafer 16 vertically in the cavity 20, a three-dimensional structure can be constructed. In this specification the terms “wafer”, “chip” or “substrate” shall be interchangeably used as equivalents of each other. In addition to allowing for out-of-plane components on a wafer 16, this process enables post-fabrication assembly of three-axis sensors 24 as described below. Electrical conductors 18 can be provided on both the out-of-plane wafer 16 and the holder wafer 14 and coupled together with the assembly process.

To provide stable mounting, an SOI wafer 14 with a very thick device layer is preferably used (on the order of 100-500 μm). Alternatively, the cavity 20 can be defined in a handle layer of an SOI wafer 14. In some cases additional wafer bonding (e.g. Si-to-Si fusion) can be used.

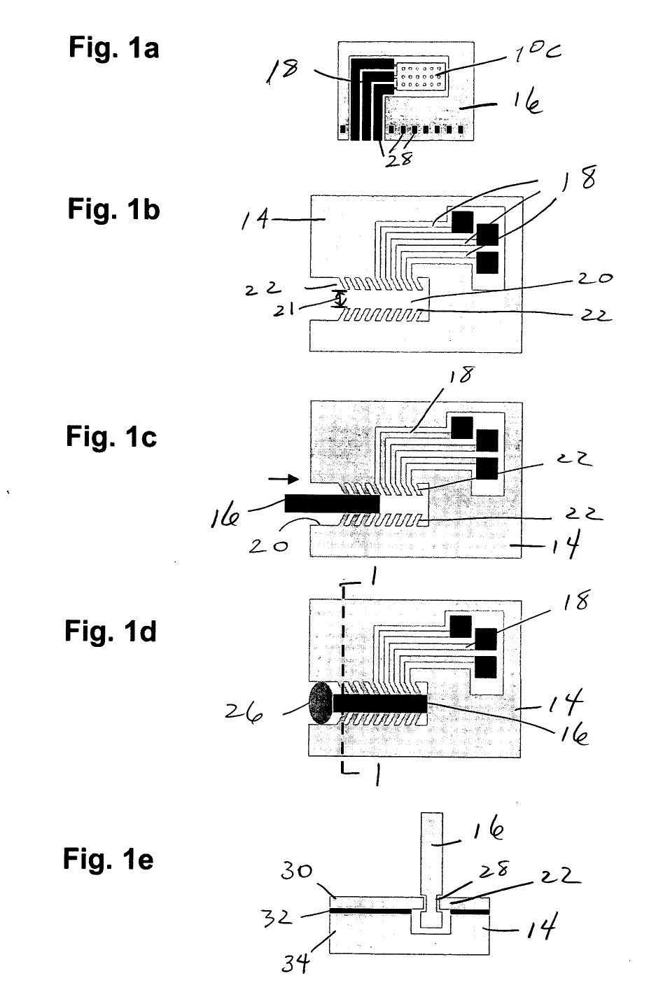

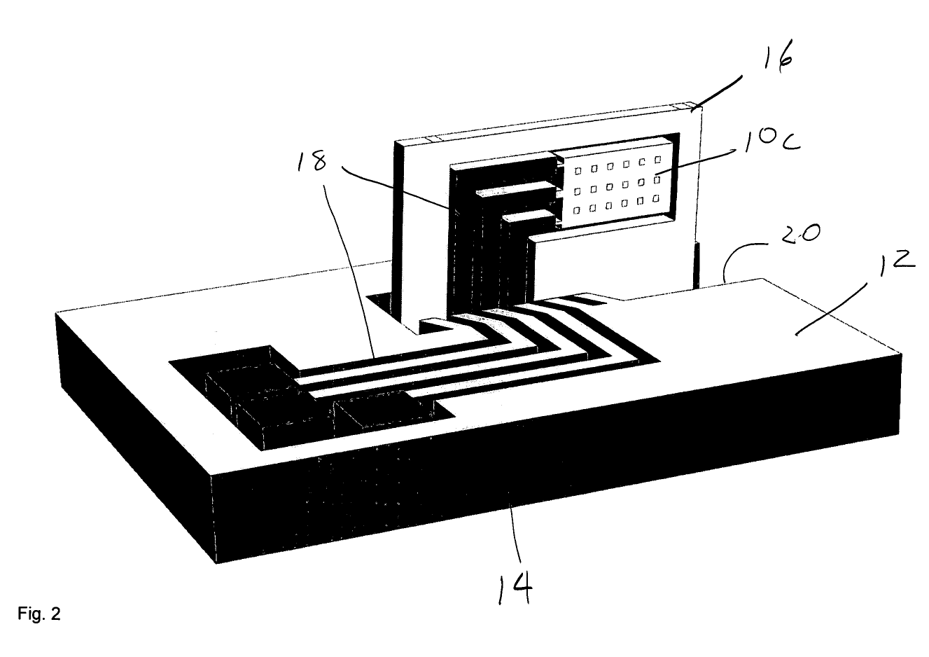

The illustrated embodiment is shown in the diagrammatic top plan views of FIGS. 1a-1d and the perspective view of FIG. 2, which illustrates the assembly process for a single-axis accelerometer 10c fabricated in a wafer 16 mounted perpendicularly to a surface 12 of a holder wafer 14. It must be understood that the assembly process can be widely applied to many other kinds of accelerometers and chip or wafer based devices, and is not to be understood as limited to the illustrated embodiment. Conductors 18 can be defined in or on both wafers 14 and 16. Ideally a thick metal layer is deposited on top of the conductors 18 to increase their conductivity. However if low-resistivity wafers 14, 16 are used, the metal layer may be omitted.

The out-of-plane wafer 16 is fabricated or provided as shown in FIG. 1a. A cavity 20 is etched, preferably using a deep reactive ion etching, DRIE, in an SOI wafer all the way through the device layer 30 to the buried oxide layer 32. Hydrofluoric acid is then utilized to dissolve the silicon oxide 32 under the fingers 22. Once the silicon oxide 32 has been partially removed, a deeper cavity 33 can optionally be etched as shown in FIG. 1e. The gap 21 defined in cavity 20 in the holder wafer 14 between opposing sets of a plurality of flexible fingers 22 as shown in the top plan view of FIG. 1b is made slightly narrower than the thickness of the out-of-plane wafer 16. When the out-of-plane wafer 16 is placed in gap 21 as shown in FIG. 1c, the angled fingers 22 in the holder wafer 14 extending into gap 21 will bend slightly and thus hold the out-of-plane wafer 16 in place. The angled fingers 22 can optionally be designed to latch into one or more predefined grooves 28 in the out-of-plane wafer 16 as illustrated in FIG. 1e. Fingers 22 may be positioned, therefore, at a predetermined depth or depths into gap 21 of wafer 14 or may be flush with surface 12. FIG. 1d shows wafer 16 fully inserted into gap 21 of wafer 14 and held in place with fingers 22. Epoxy 26 or other adhesive or means of affixation can optionally be applied between wafers 14 and 16 after the assembly of wafer 16 with wafer 14 to increase the robustness of the structure as shown in FIG. 1d. If needed, the fingers 22 in the holder wafer 14 can also provide a conductive path, eliminating the need for cumbersome wire bonding between the two perpendicular wafers 14 and 16. Conductors 18 on or in holder wafer 14 are coupled to selected ones of fingers 22, which will be aligned with conductors 18 on or in out-of-plane wafer 16, when out-of-plane wafer 16 is appropriately disposed into cavity 20 in the gap 21 between fingers 22. Although fingers are shown in the illustrated embodiment as comprised of two sets of opposing pluralities of fingers 22, it is also expressly contemplated that a single set of fingers 22 may be provided only on one side of cavity 20, or two sets of fingers 22 provided in alternating nonopposing positions on both opposing sides of cavity 20.

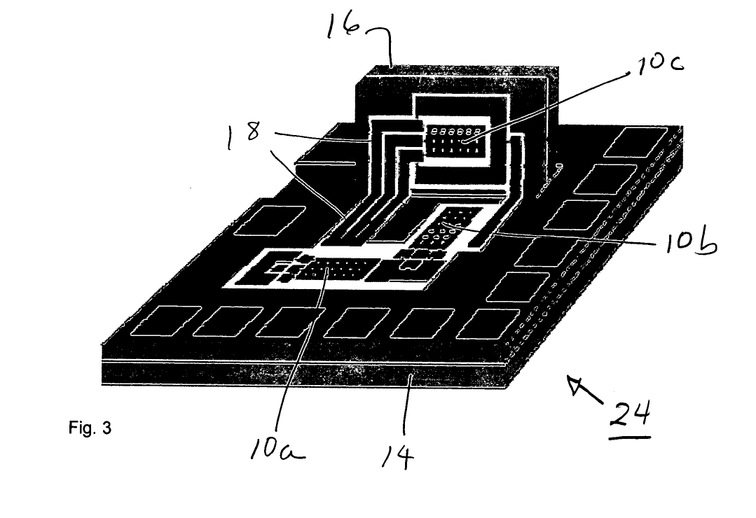

In addition to allowing for mounting of a sensor 10c perpendicular to a surface 12, this process enables post-fabrication assembly of a three-axis sensor 24. In the illustrated embodiment wafers 14 and 16 are conventional SOI wafers comprised of a substrate silicon layer, a buried silicon oxide layer, and a thick silicon device layer. By etching the holder wafer 14, sensor 10a and/or 10b can be defined in the same layer of wafer 14 that is used to hold the out-of-plane structure of wafer 16. If desired, the silicon oxide layer or any other sacrificial material in the SOI wafer 14, 16 underneath the devices or components of sensors 10a, 10b, and 10c defined in the device layer of wafers 14, 16 can be removed with hydrofluoric (HF) acid (or other appropriate etchant) to obtain free-standing components, except for those areas in the device layer without release holes which then define anchor points. For example, a three-axis accelerometer 24 assembled with this technique is depicted conceptually in FIG. 3. Two accelerometers 10a and 10b are fabricated in holder wafer 14 and each oriented along one of the two orthogonal x and y axis. Similarly, a third accelerometer 10c is fabricated in the out-of-plane wafer 16 and oriented along the orthogonal z axis.

Although the illustrated embodiment is shown in the context of assembly of piezoelectric accelerometers having the structure of the devices disclosed in the copending application, entitled “Single-Mask Fabrication Process for Linear and Angular Piezoresistive Accelerometers,” Ser. No., which is incorporated herein by reference, and which corresponds to the incorporated U.S. Provisional Patent application, Ser. No. 60/726,723, the method of the invention is expressly not limited to assembly of sensors or accelerometers. It is also possible to achieve many other types of out-of- plane devices with this assembly technique. Other types of out-of-plane assemblies that can be obtained using this process include, but are not limited to, optical lenses, diffraction gratings, and mirrors. The list of possible out-of-plane assemblies is nearly limitless and can be employed in or with any kind of MEMS device now known or later devised.

In summary it can now be appreciated that the illustrated embodiment of the invention provides a:

Fabrication process that enables three-dimensional assembly of micromachined devices;

Assembly process for achieving out-of-plane components on a wafer;

Assembly process for achieving sensors with a sensitive axis perpendicular to a plane; and

Assembly process for achieving three-axis sensors

Many alterations and modifications may be made by those having ordinary skill in the art without departing from the spirit and scope of the invention. Therefore, it must be understood that the illustrated embodiment has been set forth only for the purposes of example and that it should not be taken as limiting the invention as defined by the following invention and its various embodiments.

Therefore, it must be understood that the illustrated embodiment has been set forth only for the purposes of example and that it should not be taken as limiting the invention as defined by the following claims. For example, notwithstanding the fact that the elements of a claim are set forth below in a certain combination, it must be expressly understood that the invention includes other combinations of fewer, more or different elements, which are disclosed in above even when not initially claimed in such combinations. A teaching that two elements are combined in a claimed combination is further to be understood as also allowing for a claimed combination in which the two elements are not combined with each other, but may be used alone or combined in other combinations. The excision of any disclosed element of the invention is explicitly contemplated as within the scope of the invention.

The words used in this specification to describe the invention and its various embodiments are to be understood not only in the sense of their commonly defined meanings, but to include by special definition in this specification structure, material or acts beyond the scope of the commonly defined meanings. Thus if an element can be understood in the context of this specification as including more than one meaning, then its use in a claim must be understood as being generic to all possible meanings supported by the specification and by the word itself.

The definitions of the words or elements of the following claims are, therefore, defined in this specification to include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements in the claims below or that a single element may be substituted for two or more elements in a claim. Although elements may be described above as acting in certain combinations and even initially claimed as such, it is to be expressly understood that one or more elements from a claimed combination can in some cases be excised from the combination and that the claimed combination may be directed to a subcombination or variation of a subcombination.

Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements.

The claims are thus to be understood to include what is specifically illustrated and described above, what is conceptionally equivalent, what can be obviously substituted and also what essentially incorporates the essential idea of the invention.

We claim:

1. A method of assembling a three dimensional micromachined structure comprising:
defining a cavity in a holder wafer having a thick upper layer;
providing a plurality of fingers in the thick upper layer extending from the holder wafer into the cavity; and
disposing an out-of-plane wafer into the cavity in the holder wafer in engagement with the fingers to hold the out-of-plane wafer in place in an out-of-plane position with respect to the holder wafer.

2. The method of claim 1 further comprising providing an electrical connection through the fingers between the out-of-plane wafer and the holder wafer.

3. The method of claim 1 where disposing the out-of-plane wafer into the cavity in the holder wafer further comprises affixing the out-of-plane wafer in the cavity of the holder wafer to provide a robust structure.

4. The method of claim 1 further comprising defining at least one groove in the out-of-plane wafer for engagement with the fingers and where disposing the out-of-plane wafer into the cavity in the holder wafer comprises sliding the fingers into the groove.

5. The method of claim 4 where defining at least one groove in the out-of-plane wafer for engagement with the fingers comprises defining two sets of grooves in the out-of-plane wafer, and where disposing the out-of-plane wafer into the cavity in the holder wafer comprises sliding the fingers into the two sets of grooves.

6. The method of claim 5 where defining two grooves in the out-of-plane wafer comprises defining two opposing grooves in the out-of-plane wafer.

7. The method of claim 1 where providing the plurality of fingers in the thick upper layer extending from the holder wafer into the cavity comprises providing a single set of fingers on one side of the holder wafer.

8. The method of claim 1 where providing the plurality of fingers in the thick upper layer extending from the holder wafer into the cavity comprises providing two opposing sets of fingers in the thick upper layer extending from the holder wafer into the cavity.

9. A method of assembling a three dimensional micromachined structure including active MEMS components in a three dimensional assembly comprising:
etching a cavity in silicon-on-insulator (SOI) holder wafer having a thick device layer;
engaging an out-of-plane wafer including active MEMS devices with the holder wafer to vertically extend the out-of-plane wafer from the holder wafer, engagement of the out-of-plane wafer and holder wafer causing the out-of-plane wafer and holder wafer to be orthogonally oriented with respect to each other; and
electrically coupling the out-of-plane wafer and holder wafer together to obtain a three-dimensional active MEMS assembly.

10. The method of claim 9 where electrically coupling the out-of-plane wafer and holder wafer together comprises providing a plurality of fingers extending from the holder wafer into the cavity, and engaging the out-of-plane wafer with the holder wafer with the fingers to hold the out-of-plane wafer in place in an out-of-plane position with respect to the holder wafer and to electrically couple conductors on the out-of-plane wafer with conductors on the holder wafer.

11. The method of claim 9 where engaging the out-of-plane wafer into the cavity to extend vertically from the cavity comprises positioning three accelerometers close together with a negligible distance between a center of gravity of each of the three accelerometers.

12. A three dimensional microelectromachined apparatus (MEMS) comprising:
a holder wafer having a thick upper layer;
a cavity defined in the holder wafer;
a plurality of fingers defined in the thick upper layer extending from the holder wafer into the cavity; and
an out-of-plane wafer disposed into the cavity in the holder wafer in engagement with the fingers to hold the out-of-plane wafer in place in an out-of-plane position with respect to the holder wafer.

13. The apparatus of claim 12 further comprising an electrical connection through the fingers between the out-of-plane wafer and the holder wafer.

14. The apparatus of claim 12 where the out-of-plane wafer and the holder wafer are adapted and configured to be mutually engaged with each other by disposing the out-of-plane wafer into the cavity in the holder wafer.

15. The apparatus of claim 1 further comprising affixation means for rigidly fixing the out-of-plane wafer in the cavity of the holder wafer to provide a robust structure.

16. The apparatus of claim 12 further comprising at least one groove in the out-of-plane wafer for engagement with the fingers and where the fingers of the holder wafer are arranged and configured to slide into the groove.

17. The apparatus of claim 16 comprising two sets of grooves in the out-of-plane wafer, and where the fingers of the holder wafer are arranged and configured to slide into both sets of grooves.

18. The apparatus of claim 17 where the two grooves in the out-of-plane wafer comprise two opposing grooves in the out-of-plane wafer.

19. The apparatus of claim 12 where the plurality of fingers in the thick upper layer extending from the holder wafer into the cavity comprises two opposing sets of fingers in the thick upper layer extending from the holder wafer into the cavity.

20. A three dimensional micromachined apparatus including active microelectromachined system components in a three dimensional assembly comprising:
silicon-on-insulator (SOI) holder wafer having a thick device layer;
an etched cavity in the holder wafer;
an out-of-plane wafer including active MEMS devices vertically extending from and engaged with the holder wafer, engagement of the out-of-plane wafer and holder wafer causing the out-of-plane wafer and holder wafer to be orthogonally oriented with respect to each other; and
an electrical coupling between the out-of-plane wafer and holder wafer.

21. The apparatus of claim 20 further comprising conductors on the out-of-plane wafer and on the holder wafer and where the electrical coupling between the out-of-plane wafer and holder wafer comprises a plurality of fingers extending from the holder wafer into the cavity, the fingers engaging the out-of-plane wafer with the holder wafer to hold the out-of-plane wafer in place in an out-of-plane position with respect to the holder wafer and to electrically couple the conductors on the out-of-plane wafer with the conductors on the holder wafer.

22. The apparatus of claim 20 where the out-of-plane wafer engaged with the holder wafer comprises three accelerometers positioned close together with a negligible distance between a center of gravity of each of the three accelerometers.
